(19) United States
(12) Patent Application Publication
(10) Pub. No.: US 2009/0079031 A1
(43) Pub. Date: Mar. 26, 2009

(54) METHOD AND DEVICE WITH IMPROVED BASE ACCESS RESISTANCE FOR NPN BIPOLAR TRANSISTOR

(75) Inventors: Poh Cheng Tan, Singapore (SG); Peter Deixler, Eindhoven (NL); Cicero Silveira Vaucher, Eindhoven (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 11/916,101

(22) PCT Filed: Jun. 1, 2006
(86) PCT No.: PCT/IB2006/051767

§ 371 Date: Oct. 30, 2008

Related U.S. Application Data
(60) Provisional application No. 60/686,502, filed on Jun. 1, 2005.

(51) Int. Cl. H01L 29/732; H01L 21/331

(52) U.S. Cl. 257/578; 438/342; 257/E29.183; 257/E21.375

(57) ABSTRACT

A configuration composed of multiple short emitters still share common DTI regions and a single big piece of base poly. This allows for base current to flow in 4 directions (e.g., 2 dimensions) as opposed to only two. This significantly reduces the base resistance of the transistor that is crucial for better NPN transistor RF performance and high frequency noise performance.

This application claims priority to co-pending U.S. provisional patent application filed Jun. 1, 2005, Ser. No. 60/686,502, entitled “METHOD TO IMPROVE BASE ACCESS RESISTANCE FOR NPN BIPOLAR TRANSISTOR,” the contents of which is hereby incorporated by reference.

The invention relates generally to semiconductor device structures, and more particularly, to a semiconductor device structure having a vertical NPN transistor for high speed RF-design. NPN transistors are found in many types of transceivers including cell phones, car radar, ultra wide band radios, wireless local area networks (LAN), satellite receivers and any product sensitive to noise. Vertical NPN is an important component for high speed RF-design. The high speed and low noise performance critically depends on the base resistance.

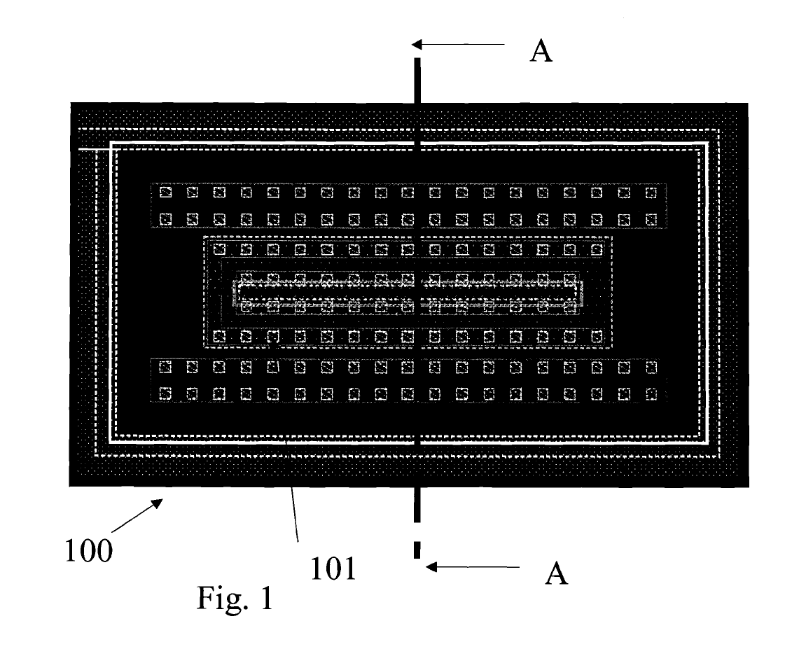

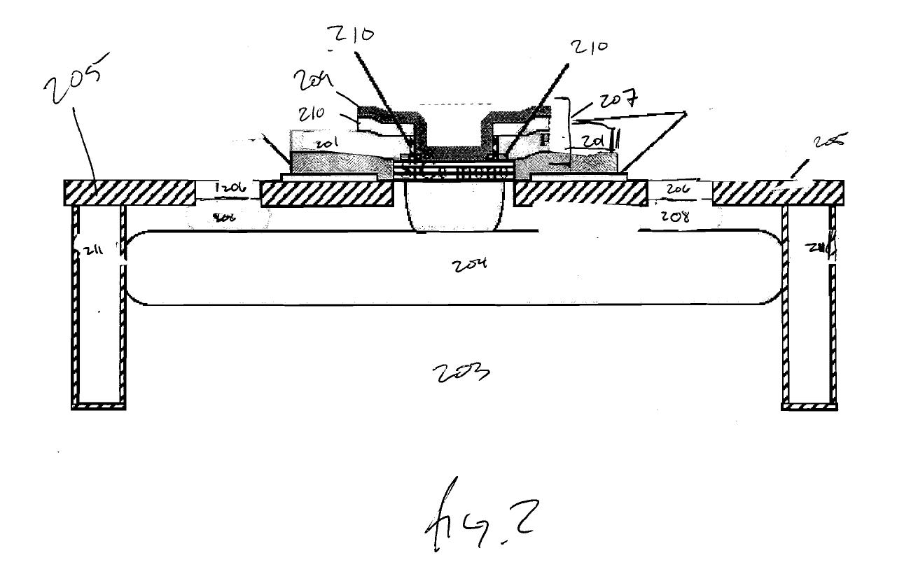

Currently, vertical NPN transistors 100 are formed on double sided base contacts as shown in FIG. 1. In the prior art, NPN transistors use a single long emitter stripe 101. FIG. 2 shows the NPN transistor 100 in cross section A-A. The NPN transistor is formed on a p-substrate 203 containing buried N layer 204. Deep trench isolation (DTI) regions 211 are present on either side of buried N layer 204. Shallow trench isolation regions 205 define n+ collector 206 and emitter 207 regions. Collector regions 206 are atop doped N regions 208. Emitter electrode 209 covers nitride/oxide spacer layers 210 which partially cover p+ base contacts 201. A layer of mono SiGe lies between Emitter region 207 and emitter electrode 209. The single long emitter stripe 101 has relatively high base resistance since base current is restricted to only flow in the two sideways directions towards the base contacts 202 on each long side of the device. The layout that includes a single long emitter stripe 101 limits the performance of a vertical NPN.

Accordingly, a need exists for an improved layout for vertical NPN transistors that improves transistor RF and noise performance.

One solution employs short emitter length NPN. However, this solution does not produce sufficient drive current to power the transistor. This solution requires connecting multiple short-emitter NPN transistors in parallel. The enables the short emitter length NPN to produce the same drive current as the single long emitter stripe configuration. The major drawback to this approach is a major increase in parasitic capacitance that significantly degrades the performance of the transistor.

A layout where the prior art single long emitter stripe is divided along its length into multiple short-emitter lengths overcomes the limitations of the prior art. A configuration composed of multiple short emitters still share common DTI regions and a single big piece of base poly. This allows for base current to flow in 4 directions (e.g., 2 dimensions) as opposed to only two. This significantly reduces the base resistance of the transistor that is crucial for better NPN transistor RF performance and high frequency noise performance. Additionally, this configuration does not require additional drive current which can degrade transistor performance. Consequently, RF performance and noise performance are improved.

These and other features of this invention will be more readily understood from the following detailed description of the various aspects of the invention taken in conjunction with the accompanying drawings in which:

FIG. 1 depicts an NPN transistor with a single long emitter stripe;

FIG. 2 depicts a cross section of the NPN transistor of FIG. 1;

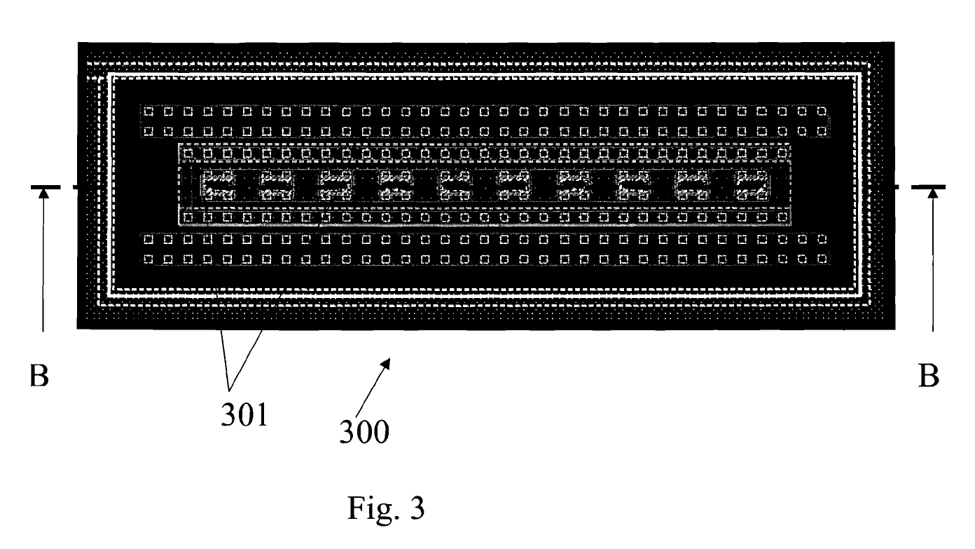

FIG. 3 depicts an NPN transistor with multiple short emitter stripes;

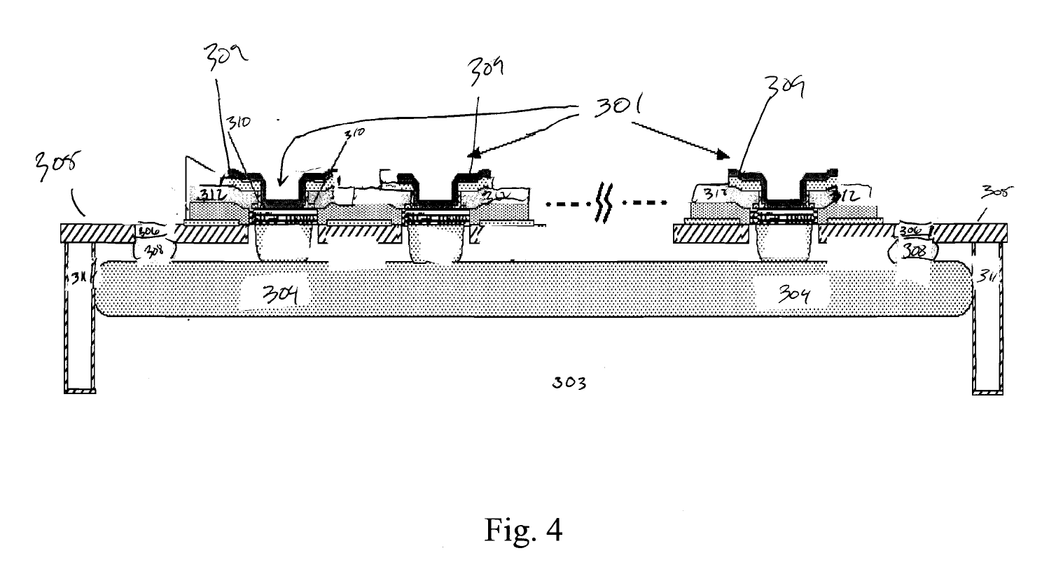

FIG. 4 depicts a cross section of the NPN transistor of FIG. 3;

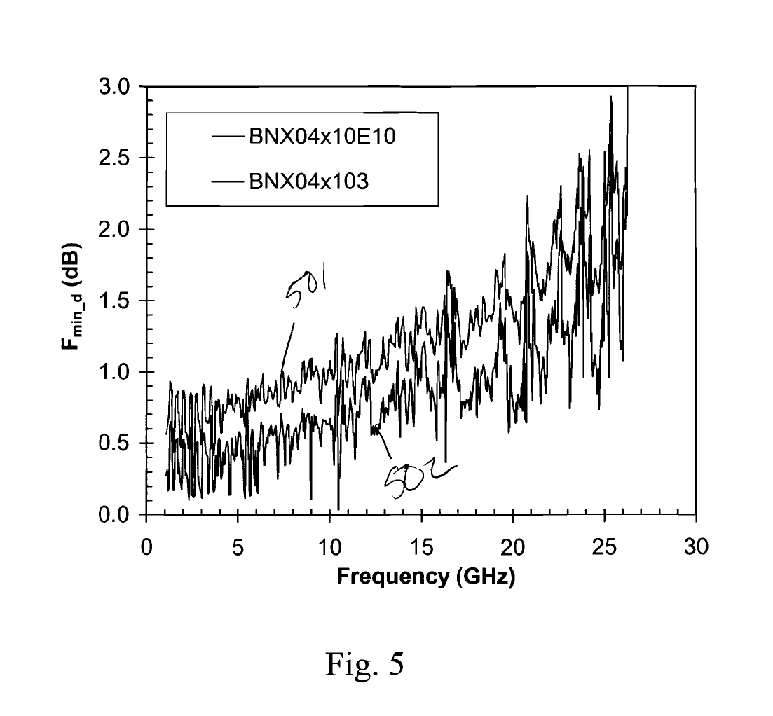

FIG. 5 depicts a chart showing minimum noise versus frequency;

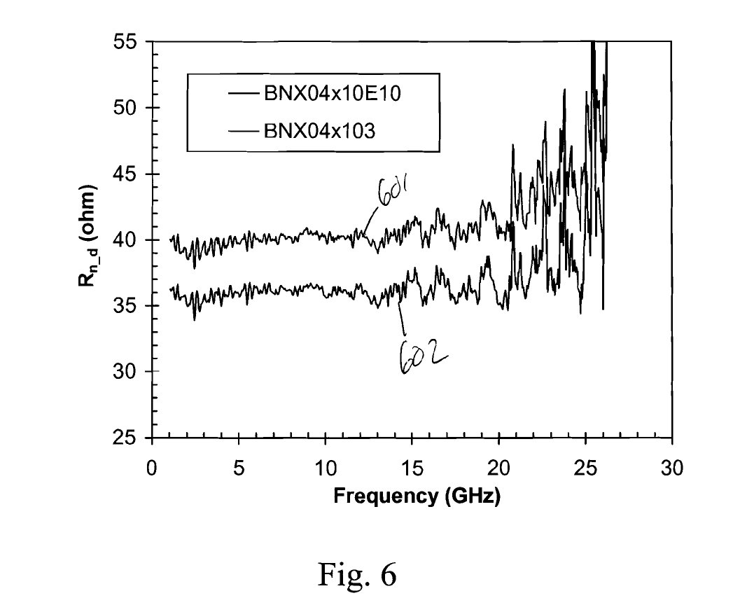

FIG. 6 depicts a chart showing noise resistance versus frequency;

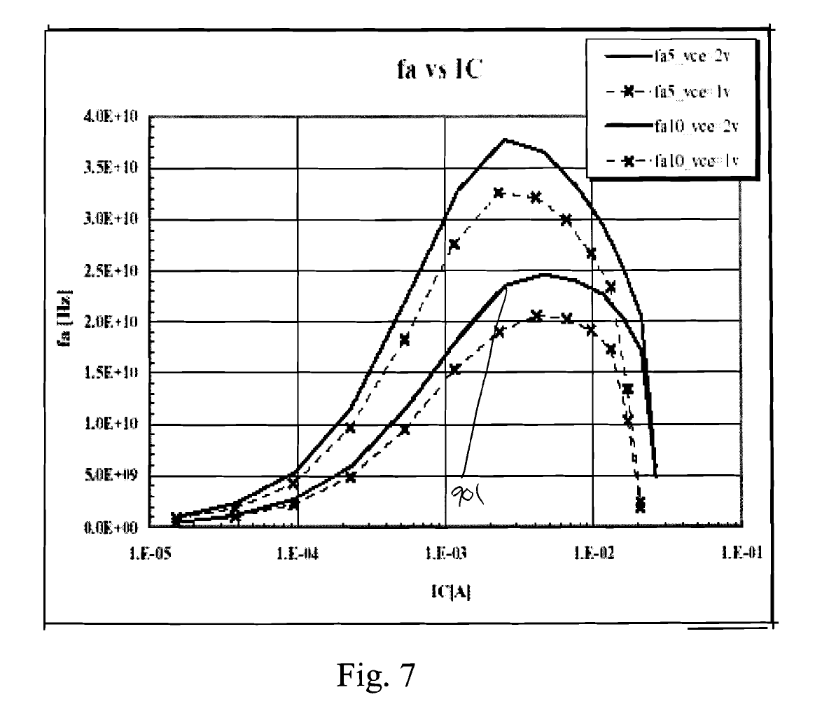

FIG. 7 depicts a chart showing frequency attenuation versus current of the single long emitter stripe configuration; and

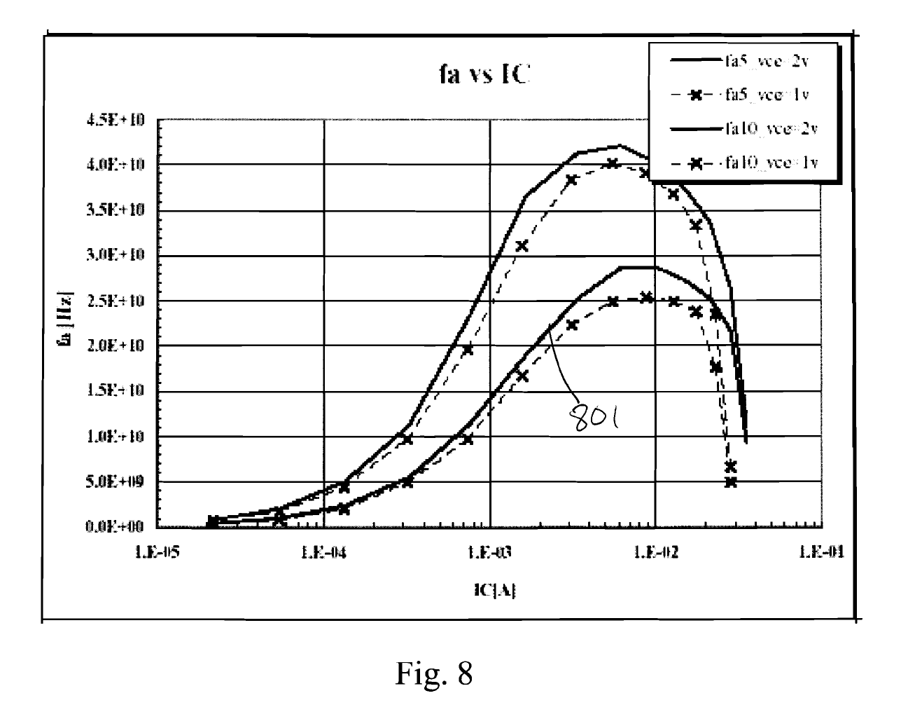

FIG. 8 depicts a chart showing frequency attenuation versus current of short multiple emitter stripes configuration.

The embodiments described herein provide a new semiconductor device having a transistor. A design and process technique is specified to significantly increase the base current flow for vertical NPN or PNP transistors formed using Bipolar or BiCMOS processes. This provides an efficient transceiver for applications such as mobile telephony, wireless LAN, ultra wide band, or any transceiver product.

One example of a transistor is a vertical NPN transistor. According to the invention, the NPN layout breaks up a conventional single long-emitter length stripe into multiple short-emitter lengths. FIG. 3 depicts an NPN transistor 300 with multiple short emitter stripes 301. The multiple short emitter stripes 301 share a common DTI region and a single piece of base poly. FIG. 4 depicts cross section B-B of FIG. 3. The NPN transistor is formed on a p-substrate 303 containing buried N layer 304. Deep trench isolation (DTI) regions 311 are present on either side of poly layer 304 and are common to the short emitter stripes 301. Shallow trench isolation regions 305 define n+ collector 306 and emitter 307 regions. Collector regions 306 are atop doped N regions 308. Emitter electrodes 309 cover nitride/oxide spacer layers 310 which partially cover p+ base contacts 312. A layer of mono SiGe lies between Emitter regions 307 and emitter electrodes 309. The multiple short emitter stripes 301 allow for base current to flow in 4 directions (i.e., 2 dimensions)-sideways and vertically toward base contacts 301 on each side of short emitter stripes 301. Note that each short emitter stripe 301 shares DTI region 304 and base poly 304. This structure reduce the base resistance of the transistor by allowing for better current flow.

FIG. 5 and FIG. 6 highlight the noise improvements of the invention. FIG. 5 shows measured frequency along the x-axis and noise figure along the y-axis. Curve 501 reflects the prior art long single line emitter structure and Curve 502 shows a short emitter stripe configuration. Curve 502 shows better minimum noise figure than Curve 501, indicating lower noise performance. FIG. 6 depicts measured frequency along the x-axis and measured noise resistance along the y-axis. Curve 601 reflects the prior art long single line emitter structure and Curve 602 shows a short emitter stripe configuration. Curve 602 shows better minimum noise figure than Curve 601, indicating better noise resistance.

FIG. 7 and FIG. 8 depict operational speed improvements of the invention. FIG. 7 shows measured current in amperes along the x-axis and fa in Hz. Fa is a critical circuit level Figure-of-Merit that describes the maximum operational speed of current-mode logic circuitry for RF devices. Curve 701 depicts a peak fa of less than 25 GHz at 2V. This curve was measured from a long single line emitter. FIG. 8 depicts measured current in amperes along the x-axis and fa in Hz for a short emitter stripe configuration. Curve 801 depicts a peak fa of approximately 20 GHz at 2V. This represents almost a 20% improvement over the single long emitter stripe configuration.

The steps involved in the fabrication processes, are essentially as follows:

(1) form a region of a first conductivity type (i.e., n) 304 in a substrate of a second conductivity type (i.e., p) 303;
(2) form a forming deep trench isolation (DTI) region 311 around the region of a first conductivity type;
(3) forming a line of least two emitter stripes atop the region of a first conductivity type by forming at least a base layer, an emitter region, and a collector region for each emitter stripe. The emitter stripes share the DTI and base region.

The transistor can be formed using a NPN or PNP bipolar process flow. The transistor can also be formed using a NPN or PNP bipolar complimentary metal oxide (BiCMOS) process flow. The transistor can also be formed to be compatible with multiple integration schemes such as double poly, selective epitaxy, non-selective epitaxy, or raised extrinsic base architecture.

The foregoing description of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of this invention as defined by the accompanying claims.

1. A vertical transistor comprising:
at least two emitter stripes each comprising:
a base region, an emitter region, and a collector region, wherein the at least two emitter stripes share a common DTI region and a single base poly.

2. The vertical transistor of claim 1, wherein the transistor is an NPN transistor.

3. The vertical transistor of claim 1, wherein the transistor is a PNP transistor.

4. A method of forming a vertical transistor comprising:
forming a region of a first conductivity type in a substrate of a second conductivity type;
forming deep trench isolation region around the region of a first conductivity type;
forming at least two emitter stripes atop the region of a first conductivity type by forming at least a base layer, an emitter region, and a collector region;
wherein the at least two emitter stripes share a common DTI region and a single base poly.

5. The method of claim 4, wherein the vertical transistor is formed using a NPN or PNP bipolar process flow.

6. The method of claim 4, wherein the vertical transistor is formed using a NPN or PNP bipolar complimentary metal oxide process flow.

7. The method of claim 4, wherein the transistor is formed to be compatible with multiple integration schemes.

8. The method of claim 7, wherein the multiple integration schemes are selected from the group consisting of: double poly, selective epitaxy, non-selective epitaxy, or raised extrinsic base architecture.

9. The method of claim 4, wherein the at least two emitter stripes are formed along a line.
